(19) United States
(12) Patent Application Publication
(10) Pub. No.: US 2026/0366188 A1
(43) Pub. Date: Nov. 19, 2026

(54) COMPONENT USING ANODIC OXIDE FILM, AND METHOD FOR MANUFACTURING SAME

(71) Applicant: POINT ENGINEERING CO., LTD., Asan-Si (KR)

(72) Inventors: Bum Mo AHN, Suwon-Si (KR); Seung Ho PARK, Hwaseong-Si (KR); Sung Hyun BYUN, Suwon-Si (KR)

(73) Assignee: POINT ENGINEERING CO., LTD., Asan-Si (KR)

(21) Appl. No.: 19/478,257

(22) PCT Filed: Apr. 9, 2024
(86) PCT No.: PCT/KR2024/004755

§ 371 Date: Oct. 23, 2025

(30) Foreign Application Priority Data
Apr. 25, 2023 (KR) 10-2023-0054321

(51) Int. Cl. C25D 11/18; C25D 7/04

(52) U.S. Cl. CPC C25D 11/18; C25D 7/04

(57) ABSTRACT

The present invention provides: a component using an anodic oxide film in which the pores of the anodic oxide film are prevented from opening during a photoresist process so that foreign substances of the photoresist do not enter the pores during a subsequent process for forming a specific material inside the pores; and a method for manufacturing same.

### CROSS-REFERENCE TO RELATED APPLICATIONS

The application claims priority to Korean patent application No. 10-2023-0054321, filed on Apr. 25, 2023, the entire contents of which are incorporated herein by reference.

### TECHNICAL FIELD

The present invention relates to a component using an anodic oxide film and a method of manufacturing the same.

### BACKGROUND

FIGS. 1A and 1B are diagrams illustrating an anodic oxide film 10 according to the prior art, where FIG. 1A is a perspective view of the anodic oxide film 10, and FIG. 1B is a cross-sectional view of FIG. 1A.

The anodic oxide film 10 refers to a film formed by anodizing a base metal M, and the pores P refer to holes formed during the process of forming the anodic oxide film by anodizing the base metal M. For example, when the base metal M is aluminum Al or an aluminum alloy, anodizing the base metal M forms an anodic oxide film 10 made of aluminum oxide Al₂O₃ on the surface of the base metal M. The anodic oxide film 10 is divided into a porous layer 11 where the pores P are formed and a barrier layer 12 where the pores P are not formed. The barrier layer 12 is located between the porous layer 11 and the base metal M, so that only one end of the pores P is opened.

Since the anodic oxide film 10 has the barrier layer 12 at the lower portion, the lower portion of the pores P is closed, and the upper portion of the pores P is opened. In order to form various materials inside the pores P, the pores P need to be opened. For this purpose, the upright arrangement state where the openings of the pores P face upward is utilized. However, when depositing a specific material inside the pores P in the upright arrangement state, the following problems arise. Crown protrusions CD exist at the openings of the pores P. The crown protrusions CD are formed at the upper portion of the porous layer 11. The upper surface of each pore P forms a concave groove, and the concave grooves overlap with adjacent concave grooves, forming the crown protrusions CD. Since the crown protrusions CD include sharp portions, the portions formed on the crown protrusions CD during the deposition of various materials become structurally weak and lack flatness control.

Meanwhile, when depositing a specific material inside the pores P of the anodic oxide film 10, various foreign substances must not be included inside the pores P. Before depositing a specific material inside the pores P, a photoresist process may be performed to form parts such as various electrodes. If the photoresist process is performed on the opened pores of the anodic oxide film or on the opened pores after removing the barrier layer 12 to open the pores P, there is a problem where fine particles generated from the photoresist enter and remain inside the pores P. These fine particles cause quality degradation and yield reduction when forming a specific material inside the pores P in subsequent processes. Additionally, when forming two electrodes or the like on the upper surface of the anodic oxide film 10, there is a structural difficulty in distinguishing the areas for forming each electrode or the like.

### PRIOR ART DOCUMENTS

### Patent Documents

(Patent Document 1) Registration Number 10-0907467 Registered Patent Gazette

### DISCLOSURE

### Technical Problem

The present invention has been devised to solve the problems of the prior art described above, and an object of the present invention is to provide a component using an anodic oxide film and a method of manufacturing the same, wherein during a photoresist process, the pores of the anodic oxide film are not opened, thereby preventing foreign substances of the photoresist from entering the pores in a subsequent process of forming a specific material inside the pores.

In addition, an object of the present invention is to provide a component using an anodic oxide film and a method of manufacturing the same, which exclude the deterioration of the quality of a deposited material caused by crown protrusions of the pores.

Furthermore, an object of the present invention is to provide a component using an anodic oxide film and a method of manufacturing the same, which enable the production of components by structurally distinguishing regions of the anodic oxide film using a region having a barrier layer and a region without a barrier layer.

### Means for Solving the Problem

To achieve the above-described objectives, a component using an anodic oxide film according to the present invention comprises: an anodic oxide film body comprising a first region having a porous layer with pores and a barrier layer without the pores disposed vertically, and a second region consisting of the porous layer only; and a functional portion formed within the pores of the second region.

In addition, the functional portion comprises: a first metal layer formed within the pores of the second region, at least a portion of which is provided on an inner wall of the pores; a functional layer at least a portion of which is provided on the first metal layer; and a second metal layer at least a portion of which is provided on the functional layer.

In addition, a first electrode electrically connected to the first metal layer; and a second electrode electrically connected to the second metal layer are included.

In addition, the first electrode is provided on top of the barrier layer of the first region.

In addition, the second electrode is provided on top of the first region or on top of the second region.

In addition, the first electrode is provided at a lower portion of the anodic oxide film body, and the second electrode is provided on top of the first region.

In addition, the barrier layer is removed in the second region so that the pores of the second region are opened at top and bottom, and the barrier layer is not removed in the first region so that tops of the pores of the first region are closed by the barrier layer and bottoms of the pores are opened.

In addition, the first metal layer is formed in a tube shape extending vertically inside the pores with a closed bottom, the functional layer is continuously formed along a surface of the first metal layer, and the functional layer is provided between the first metal layer and the second metal layer.

In addition, a vertical height of the first region is higher than a vertical height of the second region.

In addition, the first metal layer, the functional layer, and the second metal layer extend to a top of the first region.

In addition, the pores of the first region are provided as empty spaces, and the pores of the second region are filled by the functional portion.

In addition, a blocking layer is provided at a lower portion of the anodic oxide film body to close lower openings of the pores.

In addition, a vertical height of the pores of the first region is higher than a vertical height of the pores of the second region.

In addition, the functional layer is a dielectric layer or an electrolyte layer.

Meanwhile, a method of manufacturing a component using an anodic oxide film according to the present invention, which is fabricated by forming a material inside pores of an anodic oxide film body, comprises: performing a photoresist process performed before forming the material inside the pores, wherein the photoresist process is performed in a state where the pores are not opened so that fine particles of photoresist do not enter inside the pores.

In addition, the method comprises: performing a process of forming a first electrode in a first region after the photoresist process; removing a barrier layer of a second region where the first electrode is not formed to open the pores; and forming the material within the pores of the second region.

In addition, a vertical height of the first region is higher than a vertical height of the second region.

### Effect of the Invention

The present invention provides a component using an anodic oxide film and a method of manufacturing the same, wherein during the photoresist process, the pores of the anodic oxide film are not opened, thereby preventing foreign substances of the photoresist from entering the pores in subsequent processes of forming a specific material inside the pores.

In addition, the present invention provides a component using an anodic oxide film and a method of manufacturing the same, which exclude the deterioration of the quality of the deposited material caused by the crown protrusions of the pores.

Furthermore, the present invention provides a component using an anodic oxide film and a method of manufacturing the same, which enable the production of components by structurally distinguishing regions of the anodic oxide film using a region with a barrier layer and a region without a barrier layer.

### BRIEF DESCRIPTION OF DRAWINGS

FIG. 1A and FIG. 1B are drawings illustrating an anodic oxide film 10 according to the prior art, wherein FIG. 1A is a perspective view of the anodic oxide film 10, and FIG. 1B is a cross-sectional view of FIG. 1A.

FIG. 2 is a cross-sectional view illustrating an anodic oxide film body according to a preferred embodiment of the present invention.

FIG. 3 is a cross-sectional view of a component using an anodic oxide film according to a preferred first embodiment of the present invention.

FIG. 4 is a cross-sectional view of a component using an anodic oxide film according to a preferred second embodiment of the present invention.

FIG. 5 is a cross-sectional view of a component using an anodic oxide film according to a preferred third embodiment of the present invention.

FIG. 6 is a cross-sectional view of a component using an anodic oxide film according to a preferred fourth embodiment of the present invention.

FIG. 7 is a cross-sectional view of a component using an anodic oxide film according to a preferred fifth embodiment of the present invention.

FIGS. 8 to 19 are cross-sectional views for explaining a method of manufacturing a component using an anodic oxide film according to a preferred embodiment of the present invention.

### DETAILED DESCRIPTION OF THE EMBODIMENTS

The following content merely illustrates the principles of the invention. Therefore, a person skilled in the art can implement the principles of the invention and invent various equipment included in the concept and scope of the invention, even if not explicitly described or illustrated in this specification. Furthermore, all conditional terms and embodiments listed in this specification are, in principle, explicitly intended only for the purpose of understanding the concept of the invention and should not be understood as being limited to the specifically listed embodiments and conditions.

The aforementioned objectives, features, and advantages will become more apparent through the following detailed description in connection with the accompanying drawings, thereby enabling a person skilled in the art to easily implement the technical idea of the invention.

The embodiments described in this specification will be explained with reference to ideal schematic cross-sectional views and/or perspective views of the invention. The thicknesses of the films and regions shown in these drawings are exaggerated for effective explanation of the technical content. The shapes in the exemplary drawings may be modified due to manufacturing techniques and/or tolerances. Therefore, the embodiments of the invention are not limited to the specific forms shown but also include variations in shape generated according to the manufacturing process. The technical terms used in this specification are merely used to describe specific embodiments and are not intended to limit the invention. Unless the context clearly indicates otherwise, singular expressions include plural expressions. In this specification, terms such as “comprising” or “having” are intended to specify the presence of features, numbers, steps, operations, components, parts, or combinations thereof described in this specification, and should not be understood as precluding the possibility of the presence or addition of one or more other features, numbers, steps, operations, components, parts, or combinations thereof.

Hereinafter, the preferred embodiments of the invention will be described in detail with reference to the accompanying drawings. In describing various embodiments below, components performing the same function will be given the same names and reference numerals for convenience, even if the embodiments are different. Furthermore, the description of configurations and operations already explained in other embodiments will be omitted for convenience.

### Anodic Oxide Film Body 100 According to a Preferred Embodiment

Hereinafter, the anodic oxide film body 100 according to a preferred embodiment of the invention will be described.

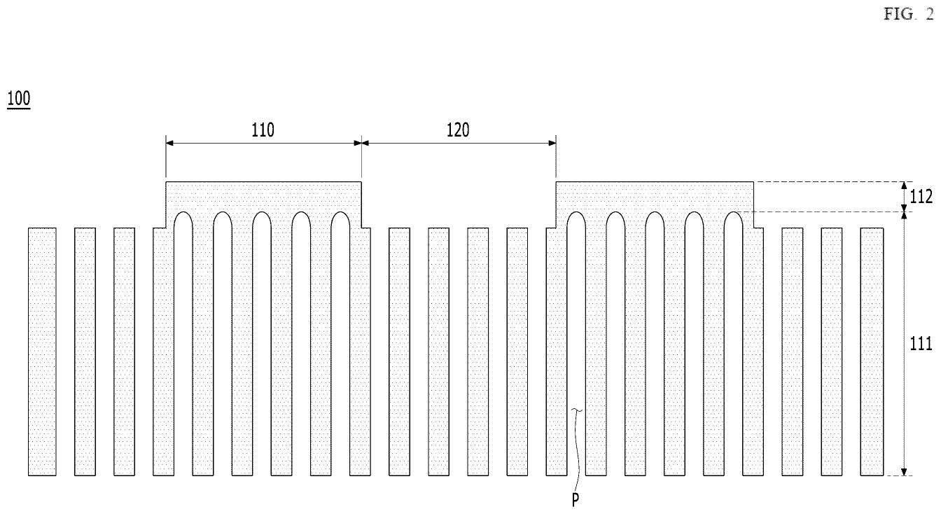

FIG. 2 illustrates a cross-sectional view of the anodic oxide film body 100 according to a preferred embodiment of the invention.

The anodic oxide film body 100 refers to a film formed by anodizing a base metal, and the pores P refer to holes formed during the process of forming the anodic oxide film by anodizing the base metal. For example, when the base metal is aluminum (Al) or an aluminum alloy, anodizing the base metal forms an anodic oxide film body 100 made of aluminum oxide (Al2O3) material on the surface of the base metal. However, the base metal is not limited thereto and may include Ta, Nb, Ti, Zr, Hf, Zn, W, Sb, or alloys thereof. The anodic oxide film body 100 thus formed is vertically divided into a porous layer 111 with pores P formed inside and a barrier layer 112 without pores P. After anodizing, when the base metal is removed, only the anodic oxide film body 100 made of aluminum oxide (Al2O3) material remains. The anodic oxide film body 100 comprises multiple pores P, and the pores P have a length of 20 μm to 200 μm and a diameter of 10 nm to 1 μm. The pitch between adjacent pores P is 20 nm to 200 nm.

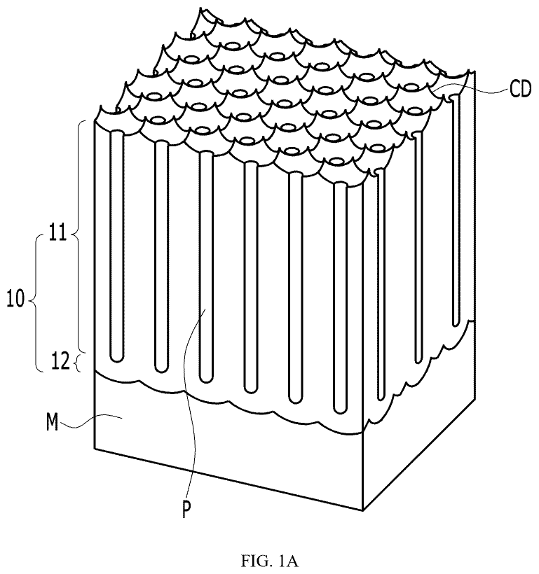

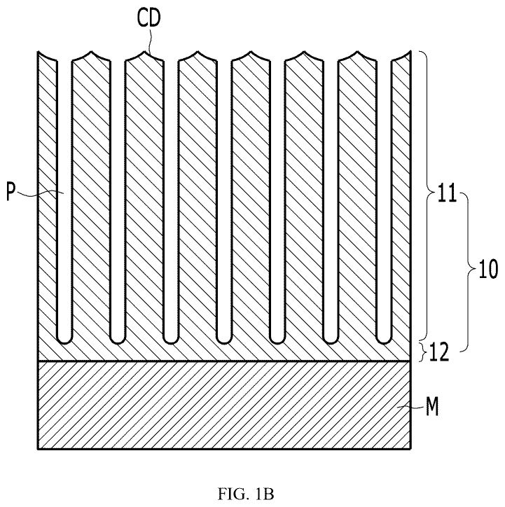

FIG. 2 shows the anodic oxide film body 10 of FIGS. 1a and 1b reversed so that the barrier layer 112 is positioned at the top and the porous layer 111 is positioned at the bottom.

The anodic oxide film body 100 structurally distinguishes two regions, including a first region 110 and a second region 120. The first region 110 comprises a porous layer 111 with pores P and a barrier layer 112 without pores P disposed vertically, and the second region 120 comprises only the porous layer 111. The first region 110 is a region where both the porous layer 111 and the barrier layer 112 are provided, whereas the second region 120 is a region where the barrier layer 112 is removed, leaving only the porous layer 111. That is, the anodic oxide film body 100 comprises a first region 110 having a porous layer 111 with pores P and a barrier layer 112 without pores P disposed vertically, and a second region 120 consisting of only the porous layer 111.

In the second region 120, as the barrier layer 112 is removed, the pores P of the second region 120 are opened at the top and bottom. In contrast, in the first region 110, as the barrier layer 112 is not removed, one end (top) of the pores P of the first region 110 is closed by the barrier layer 112, and the other end (bottom) of the pores P is opened. Material is deposited inside the pores P of the second region 120, but no material is deposited inside the pores P of the first region 110.

The vertical height of the first region 110 is higher than the vertical height of the second region 120 by an amount corresponding to the removal of the barrier layer 112 in the second region 120. Furthermore, the vertical height of the pores P of the first region 110 is higher than the vertical height of the pores P of the second region 120.

Structurally, the first region 110 is a region with the barrier layer 112, unlike the second region 120, and is formed with a higher vertical height than the second region 120. Therefore, the anodic oxide film body 100 structurally distinguishes the regions of the anodic oxide film body 100 using the first region 110 with the barrier layer 112 and the second region 120 without the barrier layer 112.

### Component 1000 Using an Anodic Oxide Film According to the First Embodiment

Next, the component 1000 using an anodic oxide film according to the first embodiment will be described.

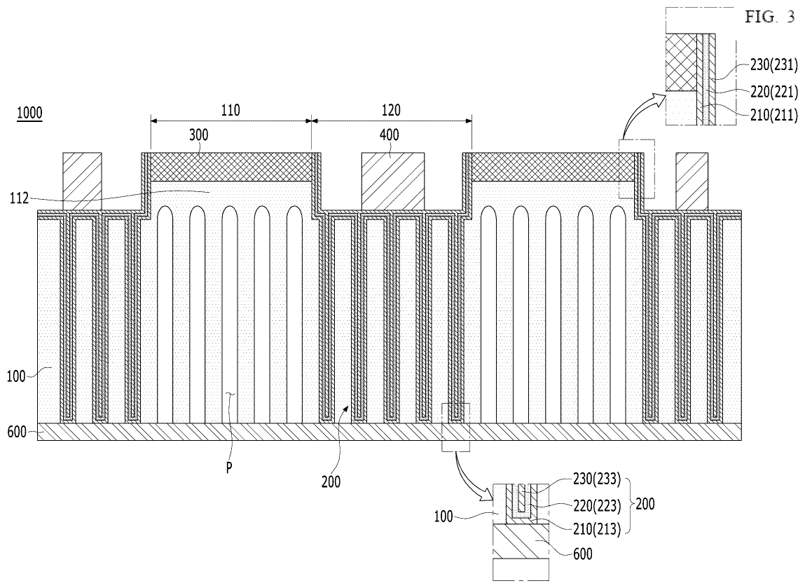

FIG. 3 is a cross-sectional view of the component 1000 using an anodic oxide film according to a preferred first embodiment of the invention.

The component 1000 using an anodic oxide film comprises an anodic oxide film body 100 having a first region 110 with a porous layer 111 with pores P and a barrier layer 112 without pores P disposed vertically, and a second region 120 consisting of only the porous layer 111.

The component 1000 using an anodic oxide film comprises a first metal layer 210, a functional layer 220, and a second metal layer 230, which are formed on the anodic oxide film body 100.

The first metal layer 210 comprises a first surface metal layer 211 formed on the surface of the anodic oxide film body 100 and a first pore metal layer 213 formed on the inner wall of the pores P. The first surface metal layer 211 is a portion formed on the surface side of the anodic oxide film body 100 in the first metal layer 210, and the first pore metal layer 213 is a portion formed on the inner wall side of the pores P in the first metal layer 210. The first surface metal layer 211 is formed entirely along the surface of the anodic oxide film body 100. The first pore metal layer 213 is formed along the inner wall of the pores P.

The functional layer 220 comprises a surface functional layer 221 formed on the first surface metal layer 211 and a pore functional layer 223 formed on the first pore metal layer 213. The surface functional layer 221 is a portion formed on the surface side of the anodic oxide film body 100 in the functional layer 220, and the pore functional layer 223 is a portion formed on the inner wall side of the pores P in the functional layer 220. The surface functional layer 221 is formed along the surface of the first surface metal layer 211, and the pore functional layer 223 is formed along the surface of the first pore metal layer 213.

The second metal layer 230 comprises a second surface metal layer 231 formed on the surface functional layer 221 and a second pore metal layer 233 formed on the pore functional layer 223. The second surface metal layer 231 is a portion formed on the surface side of the anodic oxide film body 100 in the second metal layer 230, and the second pore metal layer 233 is a portion formed on the inner wall side of the pores P in the second metal layer 230. The second surface metal layer 231 is formed along the surface of the surface functional layer 221, and the second pore metal layer 233 is formed along the surface of the pore functional layer 223.

The functional portion 200 is formed in the pores P of the second region 120. The functional portion 200 is formed inside the pores P of the second region 120. The functional portion 200 is configured by stacking the first metal layer 210, the functional layer 220, and the second metal layer 230 inside the pores P. The functional portion 200 comprises the first metal layer 210 provided on at least a portion of the inner wall of the pores P, the functional layer 220 provided on at least a portion of the first metal layer 210, and the second metal layer 230 provided on at least a portion of the functional layer 220. More specifically, the functional portion 200 comprises the first pore metal layer 213 provided on at least a portion of the inner wall of the pores P, the pore functional layer 223 provided on at least a portion of the first pore metal layer 213, and the second pore metal layer 233 provided on at least a portion of the pore functional layer 223.

The first metal layer 210 is formed in a tube shape extending vertically inside the pores P with a closed bottom, and the functional layer 220 is continuously formed along the surface of the first metal layer 210, with the functional layer 220 provided between the first metal layer 210 and the second metal layer 230. More specifically, the first pore metal layer 213 is formed in a tube shape extending vertically inside the pores P with a closed bottom, and the pore functional layer 223 is continuously formed along the surface of the first metal layer 210, with the pore functional layer 223 provided between the first pore metal layer 213 and the second pore metal layer 233.

The first electrode 300 is electrically connected to the first metal layer 210, and the second electrode 400 is electrically connected to the second metal layer 230. More specifically, the first electrode 300 is electrically connected in contact with the first surface metal layer 211, and the second electrode 400 is electrically connected in contact with the second surface metal layer 231.

The first electrode 300 is provided on top of the barrier layer 112 of the first region 110, and the second electrode 400 is provided on top of the second region 120.

The first metal layer 210, the functional layer 220, and the second metal layer 230 extend to the upper side of the first region 110. The first metal layer 210, the functional layer 220, and the second metal layer 230 extend vertically while covering the side surface of the barrier layer 112 of the first region 110 and the side surface of the first electrode 300. The upper surface of the first electrode 300 may not be provided with the first metal layer 210, the functional layer 220, and the second metal layer 230. More specifically, the first surface metal layer 211, the surface functional layer 221, and the second surface metal layer 231 extend vertically while covering the side surface of the barrier layer 112 of the first region 110 and the side surface of the first electrode 300. The upper surface of the first electrode 300 may not be provided with the first surface metal layer 211, the surface functional layer 221, and the second surface metal layer 231. The first surface metal layer 211 extending to the upper side of the first region 110 is electrically connected in contact with the first electrode 300. The second electrode 400 is formed on the upper side of the second surface metal layer 231, and the second surface metal layer 231 is electrically connected in contact with the second electrode 400.

The pores P of the first region 110 are provided as empty spaces, and the pores P of the second region 120 are filled with the functional portion 200. The first region 110 is not provided with the functional portion 200, and only the second region 120 is provided with the functional portion 200. As a result, the pores P of the anodic oxide film body 100 consist of pores P provided with the functional portion 200 and pores P not provided with the functional portion 200.

Since the vertical height of the first region 110 is higher than the vertical height of the second region 120, the distinction between the first region 110 and the second region 120 is easy through the stepped portion.

As the functional portion 200 is not formed in the first region 110 and the first electrode 300 is formed on the upper side of the first region 110, the heat generated in the first electrode 300 is thermally insulated by the barrier layer 112, minimizing the transfer of heat to the lower side of the component 1000. By using the second region 120 as a functional area utilizing the first metal layer 210, the functional layer 220, and the second metal layer 230, and using the first region 110 as a wiring area where at least a portion of the electrode such as the first electrode 300 is formed, the transfer of heat generated in the wiring area to the lower side can be minimized. Furthermore, as the first region 110 exists between the second regions 120, the transfer of heat between the second regions 120 can be minimized.

Meanwhile, when the anodic oxide film body 100 is cut and manufactured into individualized units, as the functional portion 200 is not provided in the first region 110, the first region 110 can serve as a cutting line. By using the first region 110 as a cutting line, the individualization of components becomes easier, and the application of stress to the functional portion 200 during cutting is minimized, enabling the production of high-quality components.

Alternatively, the pores P of the first region 110 may not be formed as empty spaces but may be filled with a material different from the material of the functional portion 200 to impart functionality.

A blocking layer 600 is provided at the lower side of the anodic oxide film body 100 to close the lower openings of the pores P. It prevents fine particles from entering the pores P opened at the lower side of the anodic oxide film body 100.

The blocking layer 600 may be formed of a non-conductive material. Preferably, the blocking layer 600 may include at least one of tantalum oxide (Ta2O5), aluminum oxide (Al2O3), titanium oxide (TiO2), zirconium oxide (ZrO2), or hafnium oxide (HfO2).

The blocking layer 600 may be formed by methods such as sputtering, CVD, PVD, ALD, spray coating, or coating, but is not limited thereto. Additionally, the blocking layer 600 may be manufactured in a film form and attached to the anodic oxide film body 100.

The function of the functional portion 200 varies depending on the material of the functional layer 220, and different components 1000 can be formed depending on the material constituting the functional portion 200. Here, the functional layer 220 may be a dielectric layer or an electrolyte layer. If the functional layer 220 is a dielectric layer, the component 1000 using the anodic oxide film may be a capacitor, and if the functional layer 220 is an electrolyte layer, the component 1000 using the anodic oxide film may be a battery.

If the functional layer 220 is a dielectric layer, each of the first electrode 300 and the second electrode 400 may be a metal film made of a first metal, a metal oxide film containing the first metal, a metal nitride film containing the first metal, a metal oxynitride film containing the first metal, or a combination thereof. In exemplary embodiments, the first metal may be Ti, Co, Nb, or Sn. In exemplary embodiments, the first electrode 300 and the second electrode 400 may each include Ti, titanium oxide, titanium nitride, titanium oxynitride, Co, cobalt oxide, cobalt nitride, cobalt oxynitride, Nb, niobium oxide, niobium nitride, niobium oxynitride, Sn, tin oxide, tin nitride, tin oxynitride, or a combination thereof. For example, the first electrode 300 and the second electrode 400 may each be made of TiN, CoN, NbN, SnO2, or a combination thereof.

If the functional layer 220 is a dielectric layer, the functional layer 220 may be made of a metal oxide film containing a second metal. The second metal may be Hf, Zr, Nb, Ce, or Ti. In exemplary embodiments, the functional layer 220 may be made of Al2O3, ZrO2, HfO2, Nb2O5, CeO2, or TiO2.

If the functional layer 220 is an electrolyte layer, the first electrode 300 may be a lithium transition metal oxide such as lithium cobalt oxide (LCO), lithium nickel oxide, lithium nickel cobalt oxide, lithium nickel cobalt aluminum oxide (NCA), lithium nickel cobalt manganese oxide (NCM), lithium manganate, lithium iron phosphate, nickel sulfide, copper sulfide, lithium sulfide, iron oxide, or vanadium oxide, but is not necessarily limited thereto, and any material used as a cathode active material in the relevant technical field may be used. For example, the first electrode 300 may be lithium cobalt oxide (LCO) with excellent high-voltage stability.

If the functional layer 220 is an electrolyte layer, the functional layer 220 may be at least one selected from sulfide-based solid electrolytes and oxide-based solid electrolytes, but is not necessarily limited thereto, and any inorganic solid electrolyte used in the relevant technical field may be used.

If the functional layer 220 is an electrolyte layer, the second electrode 400 may be a carbon-based anode active material and/or a non-carbon-based anode active material. The carbon-based anode active material may be crystalline carbon, amorphous carbon, or a mixture thereof. The crystalline carbon may be graphite such as natural graphite or artificial graphite in non-shaped, plate-shaped, flake-shaped, spherical, or fibrous forms, and the amorphous carbon may be soft carbon (low-temperature calcined carbon), hard carbon, mesophase pitch carbide, calcined coke, etc. The amorphous carbon may, for example, be carbon black (CB), acetylene black (AB), furnace black (FB), ketjen black (KB), graphene, etc., but is not necessarily limited thereto, and any material used in the relevant technical field may be used. The non-carbon-based anode active material may be at least one selected from the group consisting of metals capable of forming alloys with lithium, alloys of metals capable of forming alloys with lithium, and oxides of metals capable of forming alloys with lithium. The metals capable of forming alloys with lithium may, for example, be Si, Sn, Al, Ge, Pb, Bi, Sb, Si—Y alloy (where Y is an alkali metal, alkaline earth metal, group 13-16 element, transition metal, rare earth element, or a combination thereof, and is not Si), Sn—Y alloy (where Y is an alkali metal, alkaline earth metal, group 13-16 element, transition metal, rare earth element, or a combination thereof, and is not Sn), etc.

Before forming the first metal layer 210, the functional layer 220, and the second metal layer 230, the first electrode 300 is first formed. The first electrode 300 is formed in the first region 110 using a photoresist PR process, and then the barrier layer 112 at the position corresponding to the second region 120 is removed, followed by forming the first metal layer 210, the functional layer 220, and the second metal layer 230. As a result, the first electrode 300 is provided on top of the barrier layer 112 of the first region 110, and the functional portion 200 is provided inside the pores P of the second region 120.

During the process of performing the photoresist PR process using the photoresist PR, as the barrier layer 112 closes the ends of the pores P, fine particles generated from the photoresist PR do not enter the pores P, enabling the implementation of a high-quality functional portion 200.

### Component 1000 Using an Anodic Oxide Film According to the Second Embodiment

Next, the component 1000 using an anodic oxide film according to the second embodiment will be examined. However, the embodiments described below will focus on characteristic components compared to the first embodiment, and the description of components identical or similar to those in the first embodiment will be omitted.

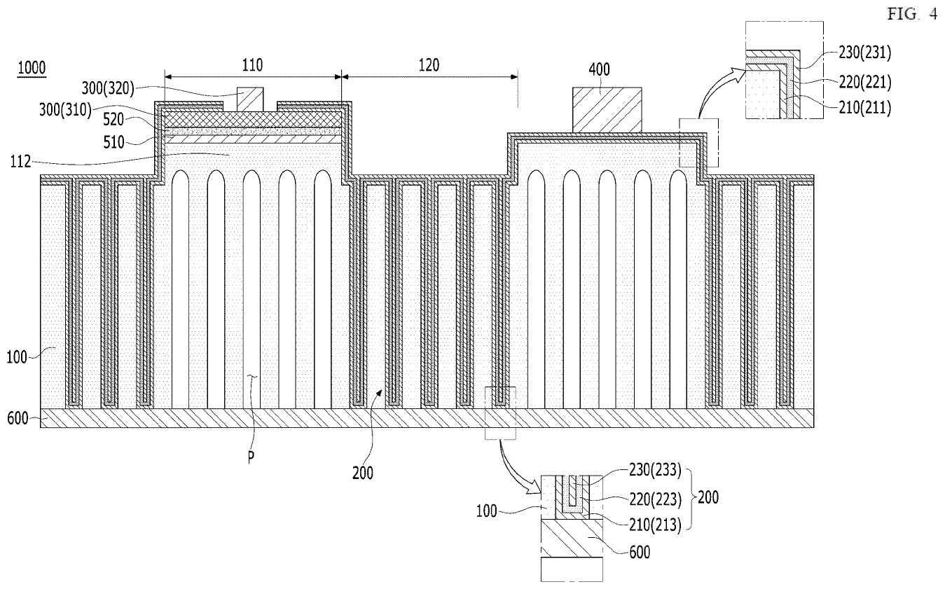

FIG. 4 is a cross-sectional view of the component 1000 using an anodic oxide film according to a preferred second embodiment of the invention.

The component 1000 using an anodic oxide film according to the second embodiment comprises a bonding layer 510 and a seed layer 520 provided on top of the barrier layer 112 of the first region 110, and a first electrode 300 provided on top of the seed layer 520.

The bonding layer 510 is a layer for securing bonding strength and may be titanium (Ti). The seed layer 520 is a pretreatment layer for facilitating the electroplating of plating metal and may be copper (Cu) or gold (Au).

The first electrode 300 comprises a first-1 electrode 310 formed with the same area as the seed layer 520 and in contact with the seed layer 520, and a first-2 electrode 320 formed with a smaller area than the first-1 electrode 310 and in contact with the first-1 electrode 310. The first metal layer 210, the functional layer 220, and the second metal layer 230 are provided inside the pores P of the second region 120 to form the functional portion 200, which is the same as the configuration of the first embodiment.

The first metal layer 210, the functional layer 220, and the second metal layer 230 extend to the upper surface of the first region 110. More specifically, the first metal layer 210, the functional layer 220, and the second metal layer 230 extend vertically while covering the side surface of the barrier layer 112 of the first region 110 and the side surface of the first electrode 300, and extend horizontally while covering a portion of the upper surface of the first-1 electrode 310. The first-2 electrode 320 is provided on the upper surface of the first-1 electrode 310 that is not covered by the first metal layer 210, the functional layer 220, and the second metal layer 230. The first-2 electrode 320 is in contact only with the first-1 electrode 310 and does not contact the first metal layer 210, the functional layer 220, or the second metal layer 230. Through this, the first electrode 300 is electrically connected to the first metal layer 210.

The second electrode 400 is provided on top of another first region 110 where the first electrode 300 is not formed. The first electrode 300 and the second electrode 400 are provided in different first regions 110.

In the first region 110 where the second electrode 400 is formed, unlike the first region 110 where the first electrode 300 is formed, the first metal layer 210, the functional layer 220, and the second metal layer 230 are entirely covered and formed. The second electrode 400 is provided in contact with the second metal layer 230 and is electrically connected to the second metal layer 230.

### Component 1000 Using an Anodic Oxide Film According to the Third Embodiment

Next, the component 1000 using an anodic oxide film according to the third embodiment will be examined. However, the embodiments described below will focus on characteristic components compared to the first embodiment, and the description of components identical or similar to those in the first embodiment will be omitted.

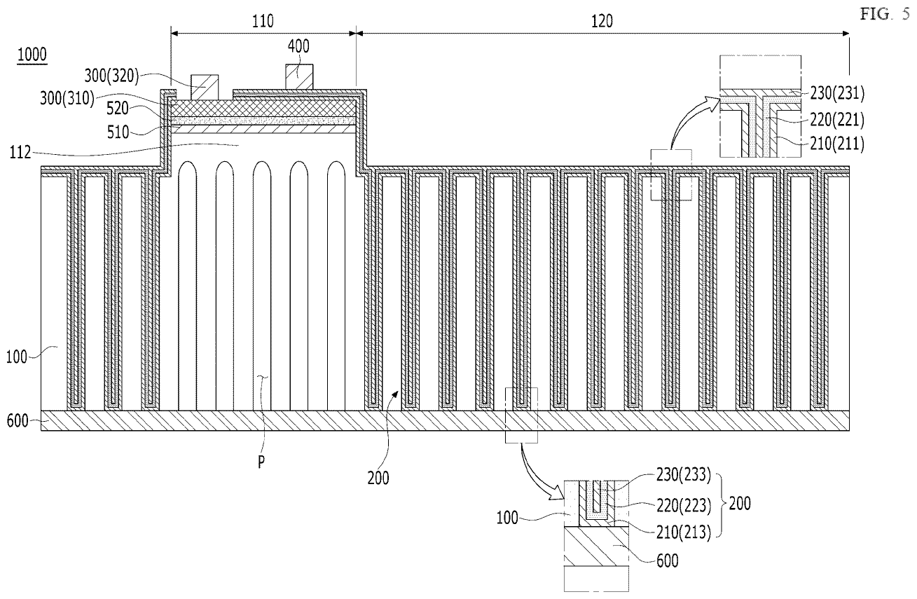

FIG. 5 is a cross-sectional view of the component 1000 using an anodic oxide film according to a preferred third embodiment of the invention.

The component 1000 using an anodic oxide film according to the third embodiment comprises a bonding layer 510 and a seed layer 520 provided on top of the barrier layer 112 of the first region 110, and a first electrode 300 provided on top of the seed layer 520. The first electrode 300 comprises a first-1 electrode 310 formed with the same area as the seed layer 520 and in contact with the seed layer 520, and a first-2 electrode 320 formed with a smaller area than the first-1 electrode 310 and in contact with the first-1 electrode 310. The first metal layer 210, the functional layer 220, and the second metal layer 230 are provided inside the pores P of the second region 120 to form the functional portion 200, which is the same as the configuration of the first embodiment.

The first metal layer 210, the functional layer 220, and the second metal layer 230 extend to the upper surface of the first region 110. More specifically, the first metal layer 210, the functional layer 220, and the second metal layer 230 extend vertically while covering the side surfaces of the barrier layer 112 of the first region 110 and the side surfaces of the first electrode 300, and extend horizontally while covering a portion of the upper surface of the first-1 electrode 310. The first-2 electrode 320 is provided on the upper surface of the first-1 electrode 310, which is not covered by the first metal layer 210, the functional layer 220, and the second metal layer 230. The first-2 electrode 320 is in contact only with the first-1 electrode 310 and does not contact the first metal layer 210, the functional layer 220, or the second metal layer 230. Through this, the first electrode 300 is electrically connected to the first metal layer 210.

The second electrode 400 is provided on the upper portion of the first region 110 where the first electrode 300 is formed. The first electrode 300 and the second electrode 400 are provided in the same first region 110. The second electrode 400 is provided in contact with the second metal layer 230 and is electrically connected to the second metal layer 230.

The first metal layer 210, the functional layer 220, and the second metal layer 230 extend to the upper portion of the first region 110, and in the extended first metal layer 210, the functional layer 220, and the second metal layer 230, the first metal layer 210 is electrically connected to the first electrode 300, and the second metal layer 230 is electrically connected to the second electrode 400.

### Component 1000 Using an Anodic Oxide Film According to the Fourth Embodiment

Next, a component 1000 using an anodic oxide film according to the fourth embodiment will be described. However, the embodiments described below will focus on characteristic components compared to the first embodiment, and descriptions of components identical or similar to those in the first embodiment will be omitted.

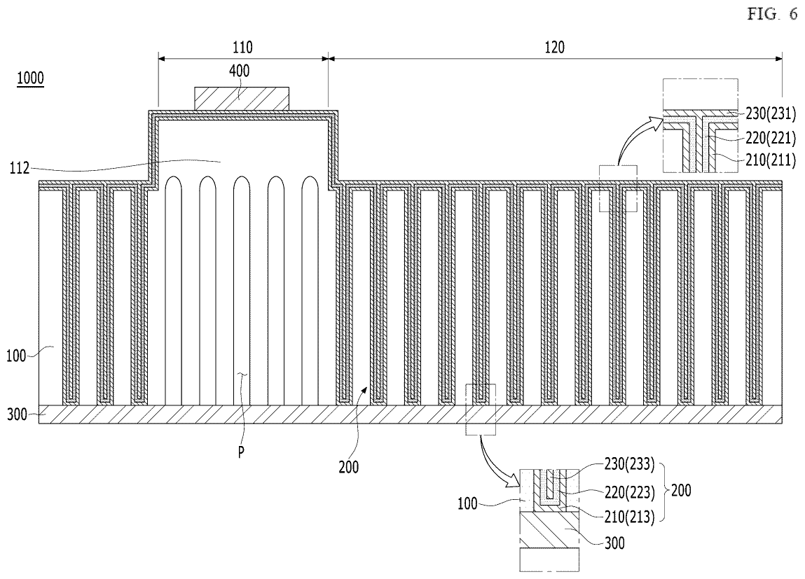

FIG. 6 is a cross-sectional view of a component 1000 using an anodic oxide film according to a preferred fourth embodiment of the present invention.

The component 1000 using an anodic oxide film according to the fourth embodiment includes a first electrode 300 provided at the lower portion of the anodic oxide film body 100 and a second electrode 400 provided at the upper portion of the first region 110. The component 1000 using an anodic oxide film according to the fourth embodiment is configured such that the blocking layer 600 provided in the first to third embodiments is composed of an electrically conductive material, and the blocking layer 600 also serves as the first electrode 300. The first metal layer 210, the functional layer 220, and the second metal layer 230 are provided inside the pores P of the second region 120 to form the functional portion 200, which is the same as the configuration of the first embodiment.

The first metal layer 210, the functional layer 220, and the second metal layer 230 are conformally formed on the anodic oxide film body 100.

The first metal layer 210 formed inside the pores P is exposed at the lower portion of the anodic oxide film body 100 and is electrically connected to the first electrode 300 provided at the lower portion of the anodic oxide film body 100.

The first metal layer 210, the functional layer 220, and the second metal layer 230 extend to the upper surface of the first region 110, and the second electrode 400 is provided in contact with the upper surface of the second metal layer 230 of the first region 110 and is electrically connected to the second metal layer 230.

### Component 1000 Using an Anodic Oxide Film According to the Fifth Embodiment

Next, a component 1000 using an anodic oxide film according to the fifth embodiment will be described. However, the embodiments described below will focus on characteristic components compared to the first embodiment, and descriptions of components identical or similar to those in the first embodiment will be omitted.

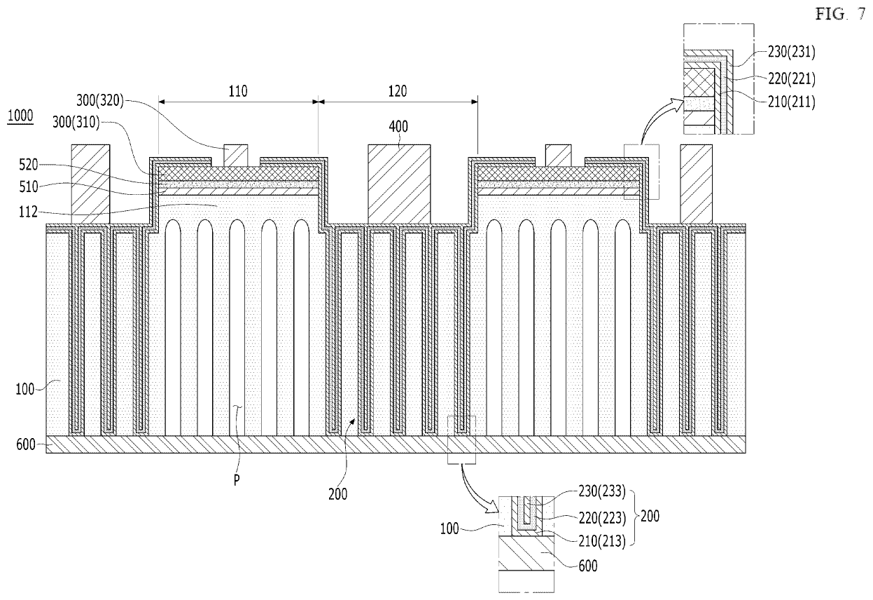

FIG. 7 is a cross-sectional view of a component 1000 using an anodic oxide film according to a preferred fifth embodiment of the present invention.

The component 1000 using an anodic oxide film according to the fifth embodiment includes a bonding layer 510 and a seed layer 520 provided on the upper portion of the barrier layer 112 of the first region 110, and a first electrode 300 provided on the upper portion of the seed layer 520. The first electrode 300 includes a first-1 electrode 310, which has the same area as the seed layer 520 and is formed in contact with the seed layer 520, and a first-2 electrode 320, which is formed with a smaller area than the first-1 electrode 310 and is formed in contact with the first-1 electrode 310.

The first metal layer 210, the functional layer 220, and the second metal layer 230 extend to the upper surface of the first region 110. More specifically, the first metal layer 210, the functional layer 220, and the second metal layer 230 extend vertically while covering the side surfaces of the barrier layer 112 of the first region 110 and the side surfaces of the first electrode 300, and extend horizontally while covering a portion of the upper surface of the first-1 electrode 310. The first-2 electrode 320 is provided on the upper surface of the first-1 electrode 310, which is not covered by the first metal layer 210, the functional layer 220, and the second metal layer 230. The first-2 electrode 320 is in contact only with the first-1 electrode 310 and does not contact the first metal layer 210, the functional layer 220, or the second metal layer 230. Through this, the first electrode 300 is electrically connected to the first metal layer 210.

The first electrode 300 is provided on the upper portion of the barrier layer 112 of the first region 110, and the second electrode 400 is provided on the upper portion of the second region 120. Through this, the first electrode 300 is electrically connected to the first metal layer 210, and the second electrode 400 is electrically connected to the second metal layer 230.

### Method of Manufacturing a Component 1000 Using an Anodic Oxide Film According to a Preferred Embodiment

Next, a method of manufacturing a component 1000 using an anodic oxide film according to a preferred embodiment of the present invention will be described. Below, the method of manufacturing a component 1000 using an anodic oxide film according to the fifth embodiment will be exemplified, but the manufacturing method described below can also be applied to the method of manufacturing a component 1000 using an anodic oxide film according to the first to fourth embodiments.

When performing a photoresist process in a state where the pores P are opened, fine particles generated from the photoresist PR may enter the inside of the pores P or block the entrances of the pores P. In such a case, there arises a problem of degradation in the quality of the material to be formed inside the pores P. According to the embodiment of the present invention, in the method of manufacturing a component 1000 using an anodic oxide film fabricated by forming a material inside the pores P of the anodic oxide film body 100, the photoresist process performed before forming the material inside the pores P is performed in a state where the pores P are not opened so that fine particles of the photoresist PR do not enter inside the pores P. Of course, after forming the material inside the pores P, it is possible to perform the photoresist process without concern for quality degradation of the functional portion 200 due to fine particles of the photoresist PR.

According to the embodiment of the present invention, the method of manufacturing a component 1000 using an anodic oxide film comprises: performing a process of forming a first electrode 300 in the first region 110 after the photoresist process; removing the barrier layer 112 of the second region 120 where the first electrode 300 is not formed to open the pores P; and forming the material within the pores P of the second region 120.

Additionally, the method of manufacturing a component 1000 using an anodic oxide film comprises: forming a blocking layer 600 that closes the openings of the pores P of the porous layer 111 in the anodic oxide film body 100 comprising the porous layer 111 and the barrier layer 112, and partially forming the first electrode 300 on the upper portion of the barrier layer 112; removing the barrier layer 112 of the region where the first electrode 300 is not formed to form the second region 120 consisting of only the porous layer 111 in the anodic oxide film body 100, and forming the first region 110 where the porous layer 111 and the barrier layer 112 are vertically provided in the region where the barrier layer 112 is not etched; forming the first metal layer 210 provided on the inner wall of the pores P, the functional layer 220 provided on the first metal layer 210, and the second metal layer 230 provided on the functional layer 220 within the pores P of the second region 120, such that the first metal layer is electrically connected to the first electrode 300; and forming the second electrode 400 provided on the upper portion of the second region 120 and electrically connected to the second metal layer 230.

Hereinafter, the details will be described with reference to the drawings.

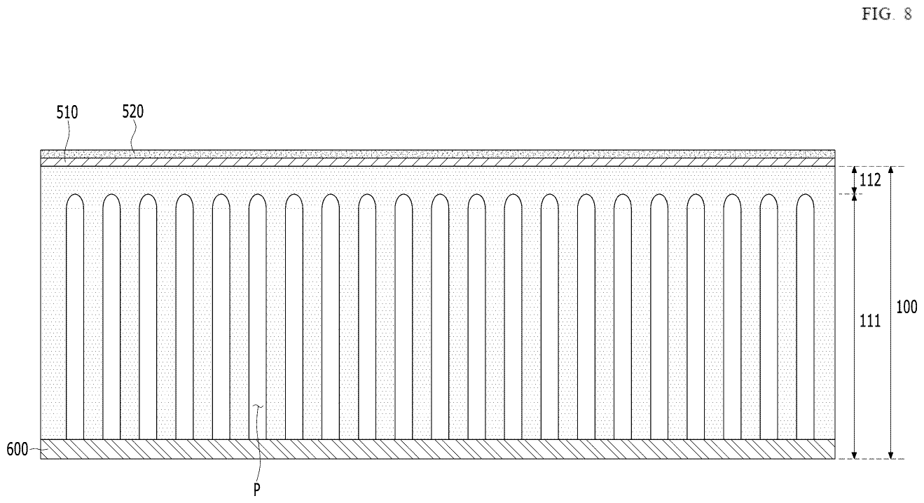

FIGS. 8 to 19 are cross-sectional views for explaining the method of manufacturing a component 1000 using an anodic oxide film according to a preferred embodiment of the present invention.

FIG. 8 shows a cross-sectional view of a state in which a bonding layer 510 and a seed layer 520 are provided on the upper surface of the anodic oxide film body 100, and a blocking layer 600 is provided on the lower surface of the anodic oxide film body 100.

The anodic oxide film body 100 refers to a film formed by anodizing a base metal M, and the pores P refer to holes formed during the process of forming the anodic oxide film by anodizing the base metal. After anodizing, when the base metal is removed, only the anodic oxide film body 100 made of aluminum oxide (Al2O3) remains. The pores P have a length of 1 μm to 200 μm and a diameter of 10 nm to 1 μm. The pitch between adjacent pores P is 20 nm to 200 nm.

One end of the pores P is closed by the barrier layer 112, and the other end of the pores P is in an open state. A blocking layer 600 is additionally formed at the open other end of the pores P to close the other end of the pores P. After forming the blocking layer 600, the anodic oxide film body 100 is inverted so that the barrier layer 112 faces upward, and the bonding layer 510 and the seed layer 520 are formed on the upper portion of the barrier layer 112. The bonding layer 510 is a layer for securing bonding strength and may be titanium (Ti). The seed layer 520 is a pretreatment layer for facilitating the electroplating of plating metal and may be copper (Cu) or gold (Au).

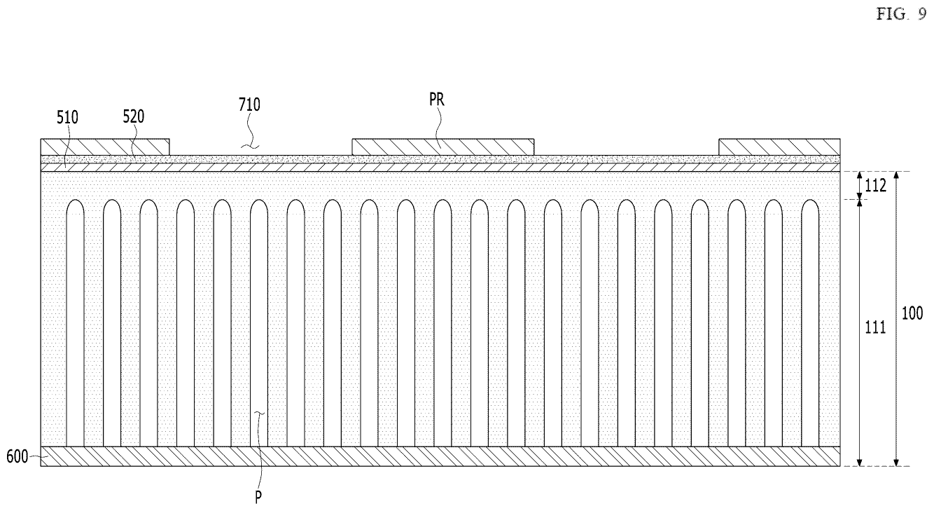

Next, referring to FIG. 9, a process of forming the photoresist PR is performed. After forming the photoresist PR on the upper portion of the seed layer 520, it is patterned to form the first opening 710. Since both ends of the pores P are already closed in the process of forming the photoresist PR, fine particles generated from the photoresist PR do not enter the inside of the pores P.

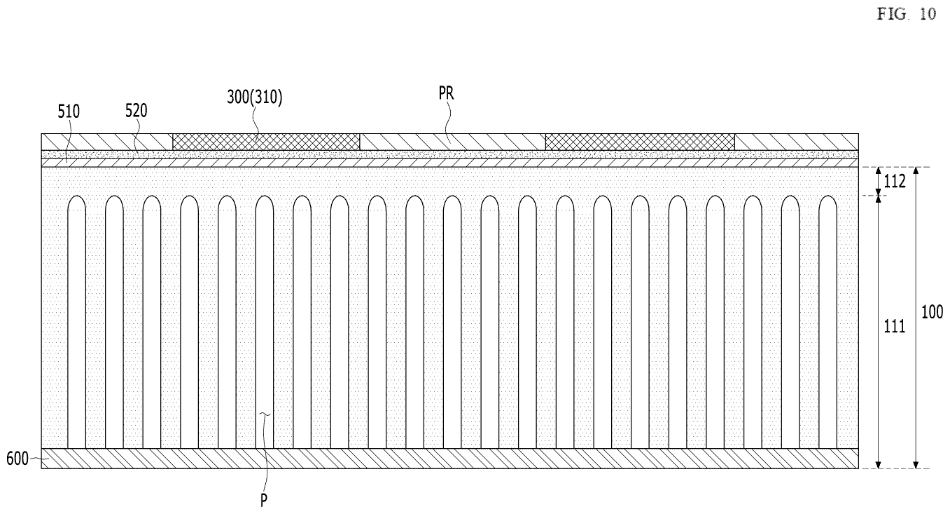

Next, referring to FIG. 10, plating is performed using the seed layer 520 to form the first-1 electrode 310 within the first opening 710. Afterward, a CMP process is performed to planarize the upper surface.

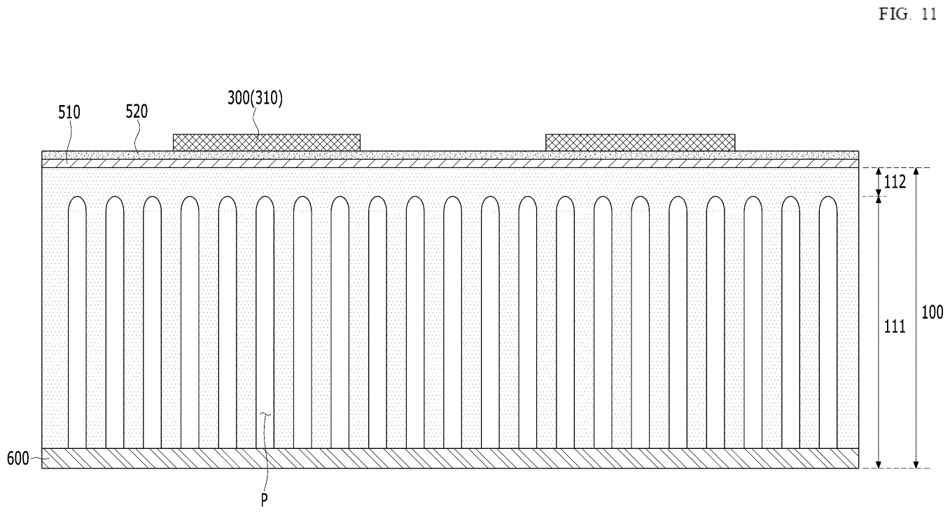

Next, referring to FIG. 11, a process of removing the photoresist PR is performed. Since both ends of the pores P are closed, fine particles generated from the photoresist PR do not enter the inside of the pores P.

The photoresist PR process includes at least a part of the processes of forming, patterning, and removing the photoresist PR, and in the series of processes of forming, patterning, and removing the photoresist PR as described above, both ends of the pores P remain closed, so there is no concern that fine particles generated from the photoresist PR will enter the inside of the pores P.

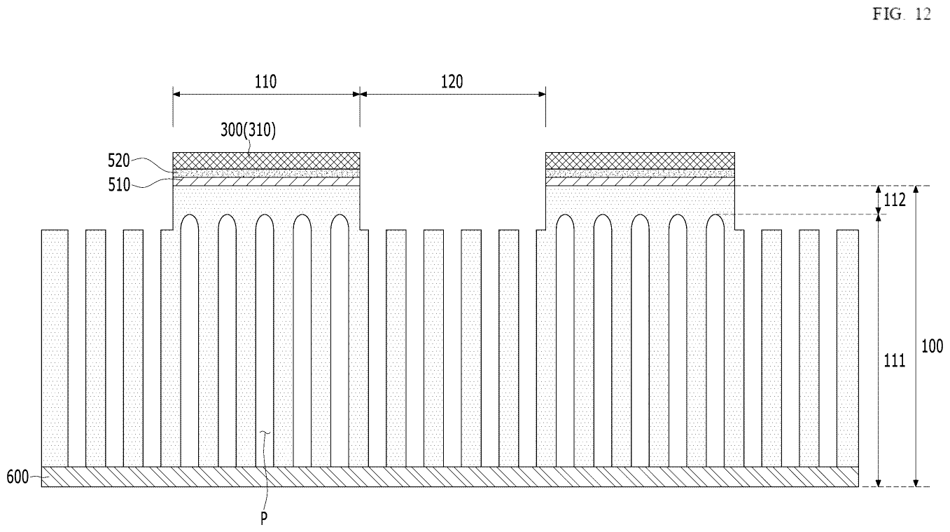

Next, referring to FIG. 12, the barrier layer 112 in a partial region of the anodic oxide film body 100 is removed. The process of removing the barrier layer 112 is performed by an etching process and preferably by dry etching. Through dry etching, a partial depth of the anodic oxide film body 100 can be precisely removed, and as a result, the first region 110 and the second region 120 are distinguished. The first region 110 is a region where both the porous layer 111 and the barrier layer 112 are provided, and the second region 120 is a region where only the porous layer 111 is provided. The first electrode 300 is provided on the upper portion of the first region 110. Since the second region 120 consists only of the porous layer 111, the upper portion of the pores P is opened.

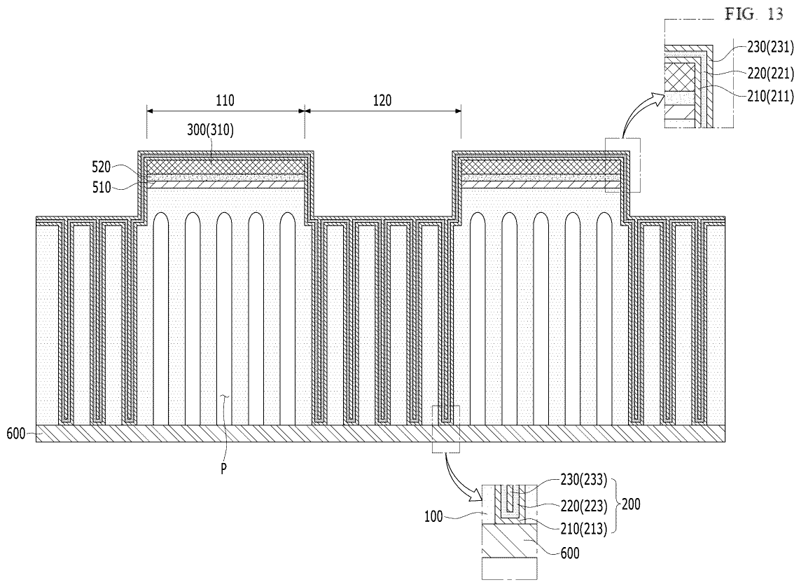

Next, referring to FIG. 13, the first metal layer 210, the functional layer 220, and the second metal layer 230 are deposited. The first metal layer 210, the functional layer 220, and the second metal layer 230 can be conformally deposited on the exposed surface by atomic layer deposition (ALD). The method of forming the first metal layer 210, the functional layer 220, and the second metal layer 230 is preferably atomic layer deposition (ALD), but is not limited thereto. Each of the first metal layer 210, the functional layer 220, and the second metal layer 230 can be formed with a thickness of 1 nm to 100 nm.

The first metal layer 210, the functional layer 220, and the second metal layer 230 are entirely formed inside the pores P of the second region 120, on the upper surface of the second region 120, and on the upper surface of the first-1 electrode 310. The first metal layer 210 is conformally formed along the surface of the anodic oxide film body 100, the functional layer 220 is conformally formed on the surface of the first metal layer 210, and the second metal layer 230 is conformally formed on the surface of the functional layer 220.

The first metal layer 210, the functional layer 220, and the second metal layer 230 formed inside the pores P form the functional portion 200. The functional portion 200 has a length of 20 μm to 200 μm and a diameter of 10 nm to 1 μm. The pitch between adjacent functional portions 200 is 20 nm to 200 nm.

The functional portion 200 is provided only in the second region 120 and is not provided in the first region 110.

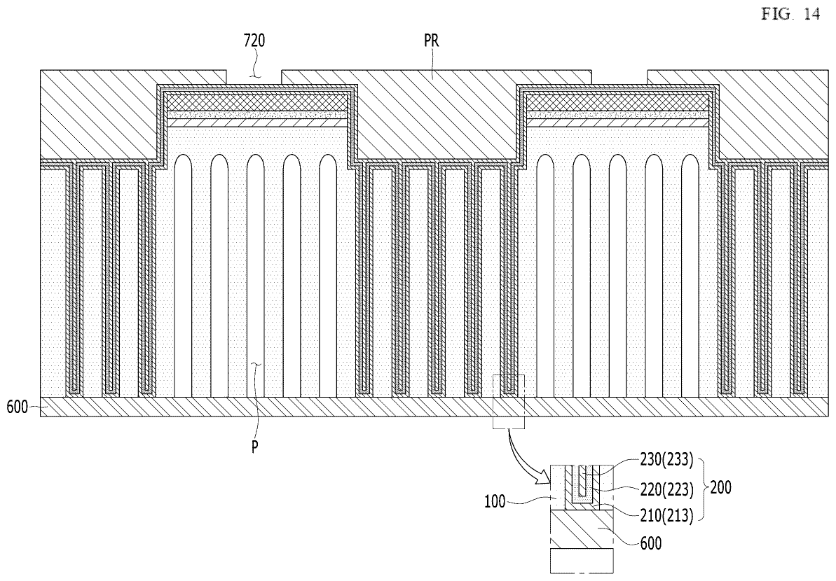

Next, referring to FIG. 14, the photoresist PR is formed and patterned to form the second opening 720. Since the first metal layer 210, the functional layer 220, and the second metal layer 230 are formed inside the pores P of the second region 120, the photoresist process performed thereafter does not affect the quality of the functional portion 200.

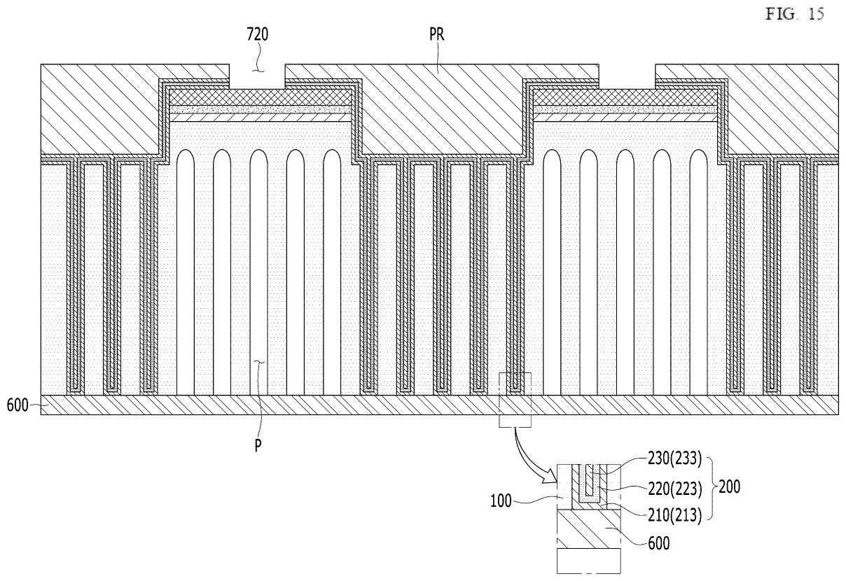

Next, referring to FIG. 15, a part of the first metal layer 210, the functional layer 220, and the second metal layer 230 formed on the first region 110 is removed using the second opening 720. The first metal layer 210, the functional layer 220, and the second metal layer 230 can be removed using a dry etching process. Through this, a part of the upper surface of the first-1 electrode 310 is exposed.

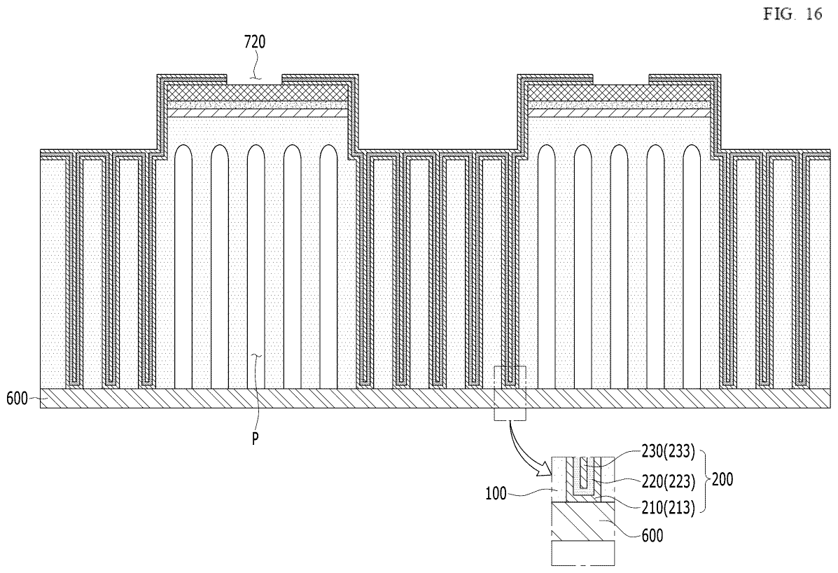

Next, referring to FIG. 16, the photoresist PR is removed.

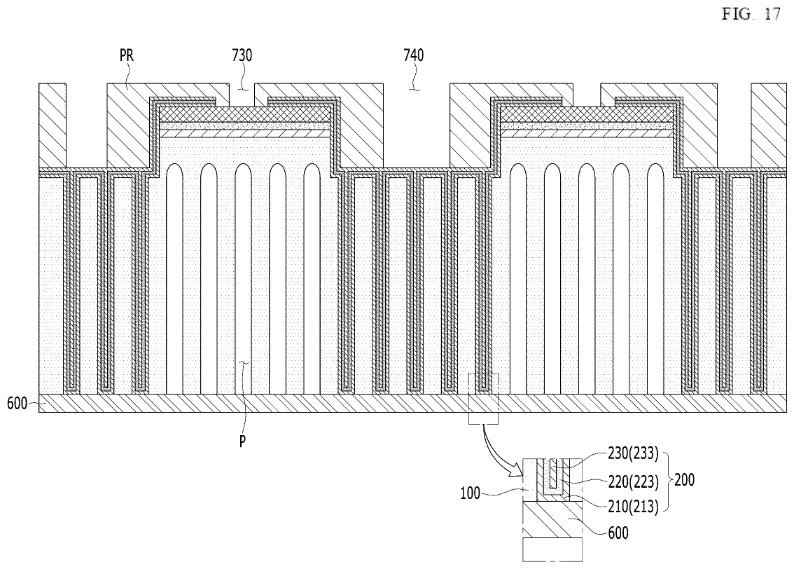

Next, referring to FIG. 17, the photoresist PR is formed again and patterned to form the third opening 730 and the fourth opening 740. The third opening 730 is formed in the first region 110, and the fourth opening 740 is formed in the second region 120. The third opening 730 is formed with a smaller area than the open area of the second opening 720 so that a part of the photoresist PR covers a part of the upper surface of the first-1 electrode 310 that is exposed.

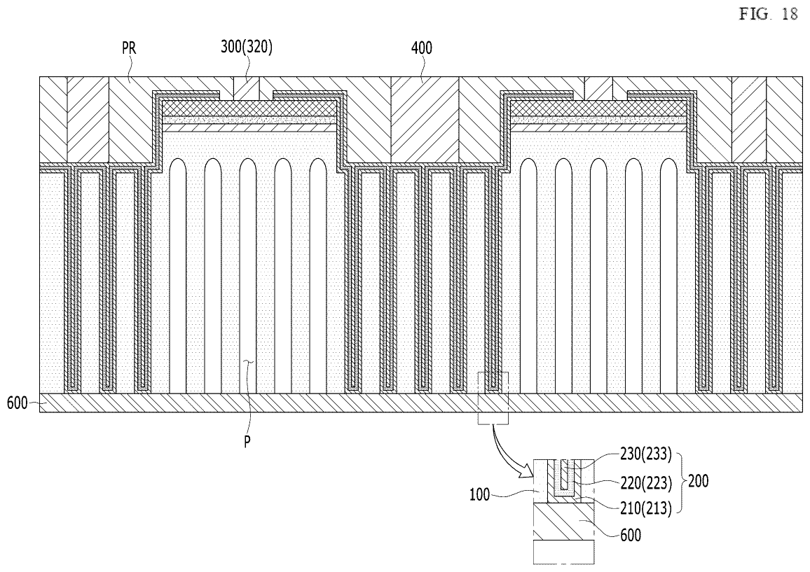

Next, referring to FIG. 18, a metal is formed in the third opening 730 and the fourth opening 740 using a method such as plating. The metal formed in the third opening 730 becomes the first-2 electrode 320, and the metal formed in the fourth opening 740 becomes the second electrode 400.

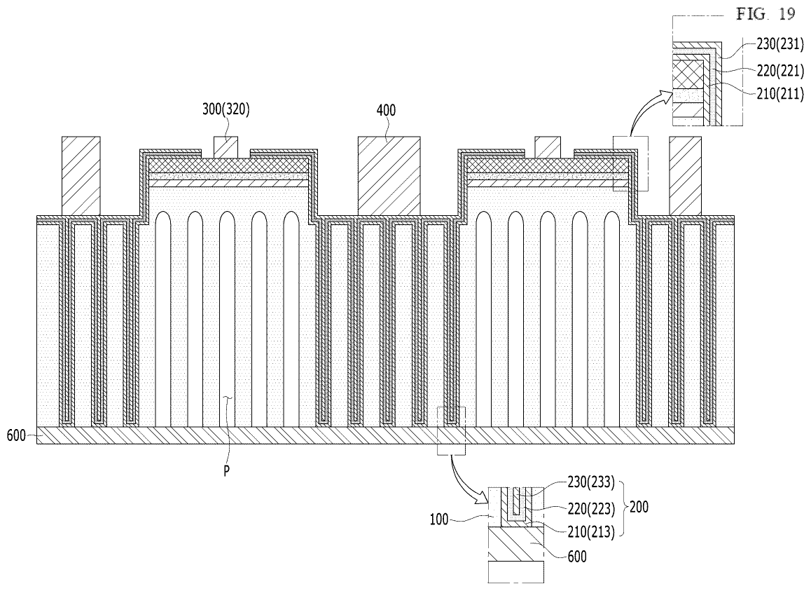

Next, referring to FIG. 19, the photoresist PR is removed.

Meanwhile, in a subsequent step, a process of cutting into individual units may be additionally performed. When cutting and fabricating into individual units, since the functional portion 200 is not provided in the first region 110, the first region 110 can serve as the cutting line. By using the first region 110 as the cutting line, the individualization of the components becomes easier, and high-quality components 1000 can be fabricated by minimizing the stress applied to the functional portion 200 during cutting.

As described above, the present invention has been described with reference to preferred embodiments, but those skilled in the art can implement the present invention in various modifications or variations without departing from the spirit and scope of the invention described in the following claims.

### DESCRIPTION OF THE REFERENCE NUMERALS IN THE DRAWINGS

100: Anodic oxide film body
200: Functional portion
300: First electrode
400: Second electrode
510: Bonding layer
520: Seed layer
600: Blocking layer

1. A component using an anodic oxide film comprising:
an anodic oxide film body comprising a first region having a porous layer with pores and a barrier layer without the pores disposed vertically, and a second region consisting of the porous layer only; and
a functional portion formed within the pores of the second region.

2. The component using an anodic oxide film of claim 1,
wherein the functional portion comprises: a first metal layer formed within the pores of the second region, at least a portion of which is provided on an inner wall of the pores; a functional layer at least a portion of which is provided on the first metal layer; and a second metal layer at least a portion of which is provided on the functional layer.

3. The component using an anodic oxide film of claim 2, comprising:
a first electrode electrically connected to the first metal layer; and
a second electrode electrically connected to the second metal layer.

4. The component using an anodic oxide film of claim 3,
wherein the first electrode is provided on top of the barrier layer of the first region.

5. The component using an anodic oxide film of claim 3,
wherein the second electrode is provided on top of the first region or on top of the second region.

6. The component using an anodic oxide film of claim 3,
wherein the first electrode is provided at a lower portion of the anodic oxide film body, and the second electrode is provided on top of the first region.

7. The component using an anodic oxide film of claim 1,
wherein the barrier layer is removed in the second region so that the pores of the second region are opened at top and bottom,
and the barrier layer is not removed in the first region so that tops of the pores of the first region are closed by the barrier layer and bottoms of the pores are opened.

8. The component using an anodic oxide film of claim 2,
wherein the first metal layer is formed in a tube shape extending vertically inside the pores with a closed bottom,
the functional layer is continuously formed along a surface of the first metal layer,
and the functional layer is provided between the first metal layer and the second metal layer.

9. The component using an anodic oxide film of claim 1,
wherein a vertical height of the first region is higher than a vertical height of the second region.

10. The component using an anodic oxide film of claim 2,
wherein the first metal layer, the functional layer and the second metal layer extend to a top of the first region.

11. The component using an anodic oxide film of claim 1,
wherein the pores of the first region are provided as empty spaces,
and the pores of the second region are filled by the functional portion.

12. The component using an anodic oxide film of claim 1, comprising:
a blocking layer provided at a lower portion of the anodic oxide film body to close lower openings of the pores.

13. The component using an anodic oxide film of claim 1,
wherein a vertical height of the pores of the first region is higher than a vertical height of the pores of the second region.

14. The component using an anodic oxide film of claim 2,
wherein the functional layer is a dielectric layer or an electrolyte layer.

15. A method of manufacturing a component using an anodic oxide film fabricated by forming a material inside pores of an anodic oxide film body, comprising:
performing a photoresist process performed before forming the material inside the pores, wherein the photoresist process is performed in a state where the pores are not opened so that fine particles of photoresist do not enter inside the pores.

16. The method of manufacturing a component using an anodic oxide film of

15. comprising:
performing a process of forming a first electrode in a first region after the photoresist process;
removing a barrier layer of a second region where the first electrode is not formed to open the pores; and
forming the material within the pores of the second region.

17. The method of manufacturing a component using an anodic oxide film of claim 16,
wherein a vertical height of the first region is higher than a vertical height of the second region.
